(19) United States
(12) Patent Application Publication
(10) Pub. No.: US 2013/0285223 A1
(43) Pub. Date: Oct. 31, 2013

(54) METHOD FOR MANUFACTURING ELECTRONIC DEVICES

(71) Applicant: STMICROELECTRONICS S.R.L., Agrate Brianza (IT)

(72) Inventor: Francesco Salamone, Acireale (IT)

(73) Assignee: STMICROELECTRONICS S.R.L., Agrate Brianza (IT)

(21) Appl. No.: 13/859,029

(22) Filed: Apr. 9, 2013

(30) Foreign Application Priority Data
Apr. 27, 2012 (IT) MI2012A000710

(51) Int. Cl. H01L 21/50; H01L 23/495

(52) U.S. Cl. CPC H01L 21/50; H01L 23/49575
USPC 257/676; 438/123

(57) ABSTRACT

A support structure includes a support cell with a support substrate, junction sacrificial portions surrounding the support substrate, and pin blocks extending from the junction sacrificial portion toward the support substrate. A semiconductor chip is mounted to the support substrate and electrically wire bonded to the pin blocks. An encapsulating body covers the chip, with the pin blocks extending from the body. A transversal groove is formed in each pin block. Surfaces of the pin block and groove are electroplated with solder material. Each pin block is sectioned at the groove to define a pin having a first end corresponding to a portion of the groove surface of the groove and a second end corresponding to the sectioned portion of the pin block that is not electroplated with solder material. Sectioning causes the separation of the chip-insulating body assembly from the junction sacrificial portions.

### PRIORITY CLAIM

This application claims priority from Italian Application for Patent No. MI2012A000710 filed Apr. 27, 2012, the disclosure of which is hereby incorporated by reference.

### TECHNICAL FIELD

The present invention relates to the field of electronics. In more detail, the present invention relates to a method for manufacturing electronic devices for signal applications and/or for power applications.

### BACKGROUND

In general, any electronic device comprises a chip (or more) of a semiconductor material on which the electronic components are integrated. The chip is usually encapsulated in a package comprising an insulating body, for example in plastic material, to be isolated and protected from the external environment. The package includes conductive pins exposed from the insulating body, which pins are coupled to corresponding conductive terminals (“pad”) of the chip. The pins act as an electrical interface between the chip and the external environment.

In the prior art various types of packages are used, which are selected according to the application scope of the electronic device.

For example, the miniaturization (scaling) of electronic devices has led to a wide spread of Surface-Mount Technology (SMT) electronic devices. In particular, an SMT electronic device type has pins which are exposed on a (lower) mounting surface of the electronic device package on a printed circuit board (PCB) (known in the art with the “No-Lead” or “Micro-Lead” names).

In relation to the end use of the device, two main application areas can be identified: (low power) signal applications, and power applications. In the first case, the chip is usually connected to a support substrate by means of glues/non-conductive materials, and the substrate is entirely embedded within the insulating body. In the case of a power device, the chip is connected to the support substrate by means of conductive materials (e.g., soldering pastes based on tin). Some power devices have a portion of the substrate that appears to be exposed from the lower face of the insulating body, so as better to tailor the heat exchange between the device and the external environment.

A typical industrial process for manufacturing electronic devices requires that a large number of chips are simultaneously encapsulated in corresponding packages through the execution of the following sequence of operations.

Making, for example, reference to an SMT electronic device for signal applications (similar considerations may be however applied to devices for power applications), the first operation involves the use of a common support structure (leadframe) in conductive material, for example copper, comprising for each electronic device to be assembled a corresponding support cell comprising a support substrate for the chip and junction sacrificial portions surrounding the support substrate. Pin blocks (precursors of the pins in the electronic devices) extend from the junction sacrificial portions towards the support substrate. In the support structure, the support substrates, the junction sacrificial portions and the pin blocks of all the electronic devices are connected together to form a single body (leadframe).

The next operation provides that a respective semiconductor material chip is connected to each support substrate. This operation is commonly referred to as “die attach”. For example, in the case of electronic devices for signal applications, this operation typically involves the use of epoxy glue.

The conductive terminals of each chip are then electrically coupled to ends of the corresponding pin blocks in the support structure, for example using interconnection wires, having circular cross-section, or interconnection twin leads, having rectangular cross-section, in conductive material. This operation is commonly referred to as “wire bonding”.

The next step provides for encapsulating the chips into insulating packages; this operation can be for example performed by injection molding of plastic material on the support structure. This operation is commonly referred to as “molding” operation.

As a result of the molding operation, excess plastic material unavoidably accumulates on the support structure, which is removed in a subsequent operation. This operation is commonly referred to as “deflashing”.

FIG. 1 is a plan view of a portion of the support structure in which four electronic devices 100(i) (i=1, 2, 3, 4) at the end of the deflashing operation are visible. At this point of the manufacturing process, the chip (not visible in the figure) of each electronic device 100(i) has already been encapsulated in a respective insulating body 110, the rear face of which is visible in the figure and identified with the reference 120. The support structure, globally identified with reference 130, comprises junction sacrificial portions 140 which surround each electronic device 100(i). Two electronic devices 100(i) that are adjacent in the support structure 130, such as devices 100(1) and 100(2), are mutually connected through a respective junction sacrificial portion 140. Pin blocks 150 extend from the edges of the junction sacrificial portions 140 facing the generic electronic device 100(i) up to reach the interior of the electronic device 100(i) itself through the insulating body 110; in particular, each pin block 150 is an element having a substantially parallelepiped shape, with side 152, 154, bottom 156 and top (not visible in the figure) faces which extend substantially along a direction perpendicular to the edge of the junction sacrificial portion 140; the upper face and the lower face 156 of the pin blocks 150 are substantially parallel to the rear face 120 of the insulating body, while the side faces 152, 154 are substantially perpendicular to the rear face 120 of the insulating body. The ends of the pin blocks 150 located within the insulating body 110, and therefore not visible in figure, are electrically connected to the conductive terminals of the chip encapsulated in the insulating body during the previous wire bonding operation.

The operation subsequent to the deflashing operation, commonly referred to as the “plating” operation, provides for covering the exposed faces of the support structure 130—including in particular the faces of the pin blocks 150—with a soldering material (for example tin) through plating. Typically, the soldering material is applied through electroplating, by immersing the support structure 130 in a galvanic bath containing an aqueous solution of the salt of the material to be deposited (e.g., a tin salt) and imposing a potential difference, for example by means of a current generator, between the support structure 130 (which acts as a cathode) and another element (that acts as an anode) which is also immersed in the plating bath. In this way, at the end of the operation, on the exposed surfaces of the support structure 130—including in particular the exposed faces of the pin blocks 150—a thin layer of the desired soldering material is formed.

The next operation, referred to in the art as the “cropping” operation, provides for the separation of electronic devices 100(i) by the support structure 130. This operation is performed by sectioning the pin blocks 150 along section planes 160 perpendicular to the face 156.

FIG. 2 is a perspective view of an electronic device 100(i) obtained with a manufacturing process known in the art, such as the manufacturing process just described. The electronic device 100(i) presents a plurality of pins 200 exposed from the insulating body 110 obtained from the pin blocks 150. In particular, each pin 200 is a portion of a respective pin block 150 of the support structure 130 (see FIG. 1) produced as a result of the sectioning carried out during the cropping. The pins 200 of an electronic device 100(i) produced with the just described manufacturing process have a (relatively) large surface portion which is not covered by the soldering material. Referring in particular to FIG. 2, the exposed two side faces 205, 210, the upper face 215 and lower face 220 of the generic pin 200 are coated with the soldering material (e.g., tin) deposited during the plating operation. Specifically, the upper face 215 and the lower face 220 are coated with the soldering material in a substantially uniform manner, while the two side faces 205, 210 are coated in a non-uniform manner due to the presence of residues of plastic material deposited during the molding step and not removed during the deflashing process. On the contrary, the exposed front face 225 of the pin 200 is instead formed by the conductive material of the support structure 130 (e.g., copper), since the soldering material layer has been deposited prior to the cropping operation, i.e., with the pin blocks 150 still intact.

The electronic device 100(i) is at this point ready to be mounted on a printed circuit board (not shown). In the surface mount technology (SMT) the pins 200 are connected, through solder pastes (for example based on tin) applied on the lower faces 220, to corresponding conductive tracks of the printed circuit board by means of a slight pressure, and are therefore soldered on them by melting the solder paste. Being the front face 225 of pins 200 substantially free of soldering material, except at most (if any) the presence of small burrs coming from the upper 215 and/or lower 220 faces that originated during the cropping operations, when the solder paste contact with the lower faces 220 of the pins 200 begins to melt, the molten material remains confined below the pin 200 themselves, since the front face 225 is formed by a material (copper) having a low degree of wettability, consequent to its oxidation. Therefore, in order to check whether the electronic device 100(i) has been properly connected to the printed circuit board, it is necessary to access the lower part of the electronic device in contact with the printed circuit board to inspect the bottom faces of the pins, operation which is very uncomfortable and difficult.

### SUMMARY

In general terms, the solution according with one or more embodiments is based on the idea of forming transversal grooves on the pin blocks before depositing the soldering material, then depositing the soldering material on the inner surfaces of the grooves and finally cutting the pin blocks at the grooves.

In particular, one aspect relates to a method for manufacturing electronic devices, comprising the phase of providing a support structure in conductive material comprising a support cell for each electronic device to be manufactured. Each support cell comprises a support substrate, junction sacrificial portions surrounding the substrate support, and pin blocks which extend from the junction sacrificial portions towards the substrate support. Each pin block has a first end connected to a junction sacrificial portion and a second end opposite to the first end. The method further comprises for each support cell connecting a semiconductor material chip integrating at least one electronic component to the corresponding support substrate, connecting terminals of the chip to the second ends of respective pin blocks of the support cell, and encapsulating the chip and the second ends of the pin blocks into a corresponding insulating body. The method further comprises for each support cell removing a portion of conductive material from each pin block between the first and the second ends to form a corresponding groove transversal to the pin block itself, covering the pin blocks and the inner surfaces of the corresponding grooves with a soldering material, and sectioning each pin block at the corresponding groove to obtain a corresponding pin having a first end corresponding to a portion of the inner surface of the groove and a second end corresponding to the second end of the pin block. Said sectioning causes the separation of the chip-insulating body-pins assembly from the junction sacrificial portions.

### BRIEF DESCRIPTION OF THE DRAWINGS

A solution in accordance with one or more embodiments of the invention, as well as further features and advantages thereof, will be better understood with reference to the following detailed description, given purely by way of non-limiting example, to be read in conjunction with the accompanying drawings (in which corresponding elements are indicated with the same or similar references and their explanation is not repeated for brevity). In this respect, it is expressly understood that the figures are not necessarily to scale (with some details that may be exaggerated and/or simplified) and that, unless otherwise indicated, they are simply used to conceptually illustrate the described structures and procedures. In particular:

FIG. 1 is a plan view of a portion of a support structure in which four electronic devices (not yet separated) are visible;

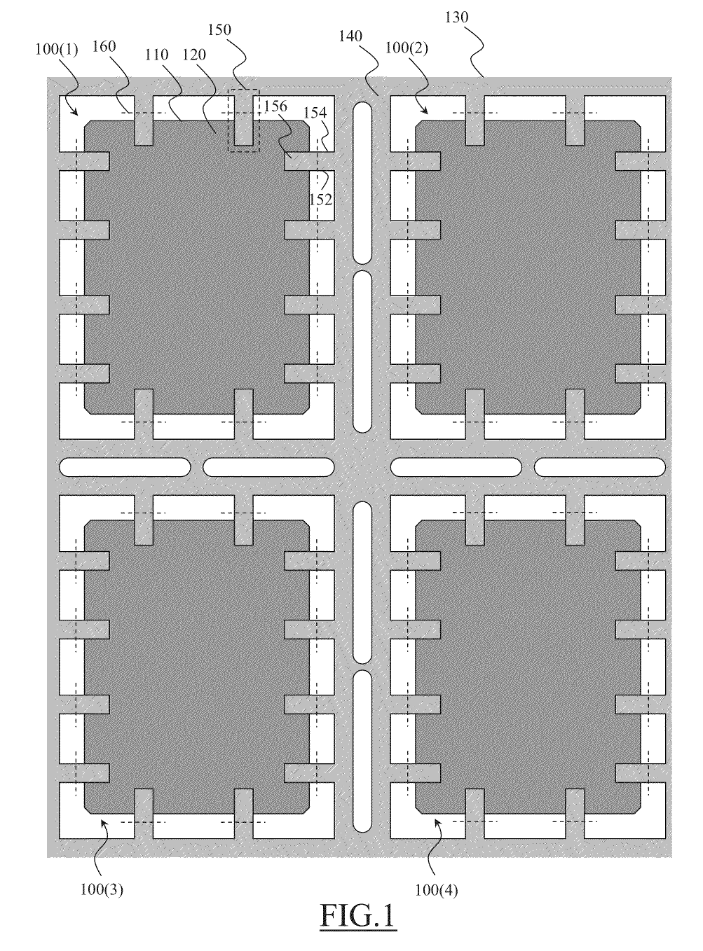

FIG. 2 is a perspective view of an electronic device obtained by a manufacturing process known in the state of the art;

FIG. 3 is a plan view of a portion of a support structure in which four electronic devices are visible during the formation of grooves on pin blocks according to an embodiment;

FIG. 4 is a sectional view of the support structure and the electronic devices of FIG. 3 taken along the section line III-III;

FIG. 5 is a bottom perspective view of a detail of FIG. 3, and

FIG. 6 is a perspective view of an electronic device obtained by a manufacturing process in accordance with an embodiment.

### DETAILED DESCRIPTION OF THE DRAWINGS

An industrial process for the manufacturing of electronic devices will now be described.

In accordance with an embodiment, the manufacturing process proceeds as described above, until the molding phase (and possibly the subsequent deflashing phase).

Before carrying out the plating operation for the deposition of a layer of soldering material (e.g., tin) on the support structure, and in particular on the pin blocks, the manufacturing process in accordance with an embodiment provides for the execution of an additional operation dedicated to the formation of grooves on the pin blocks.

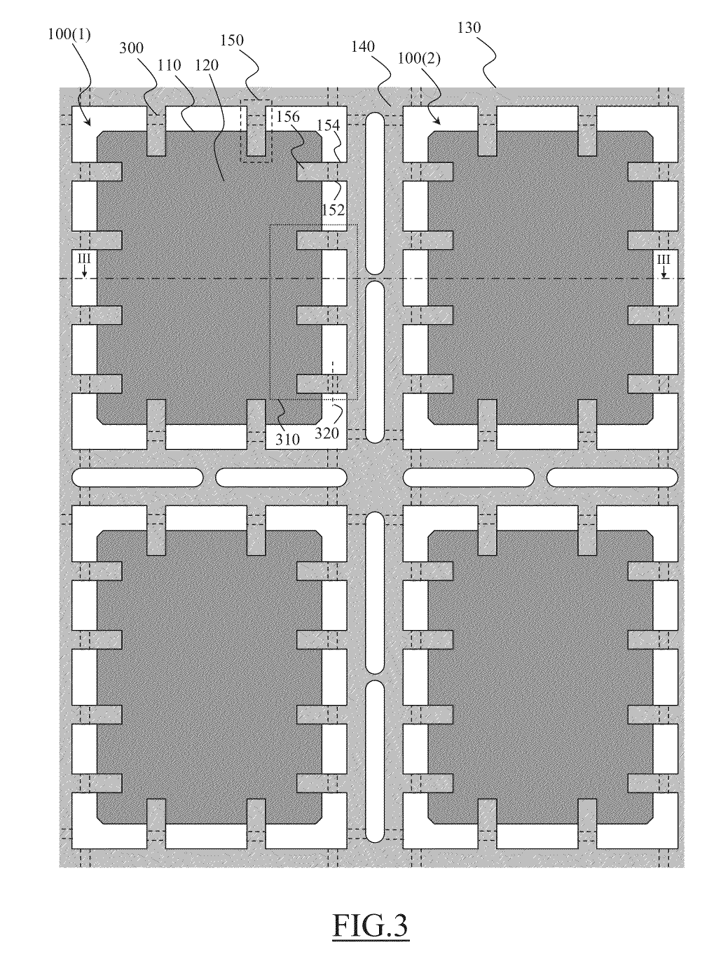

In particular, as shown in FIG. 3, from each pin block 150 of the support structure 130 a portion of material 300 is removed (for example by milling or grinding) starting from the lower face 156, forming a groove that transversally crosses the pin block 150 itself from a side face 152 to the opposite side face 154.

Similar considerations may also apply in case the removal of material from the pin blocks is carried out starting from the upper face of the pin block.

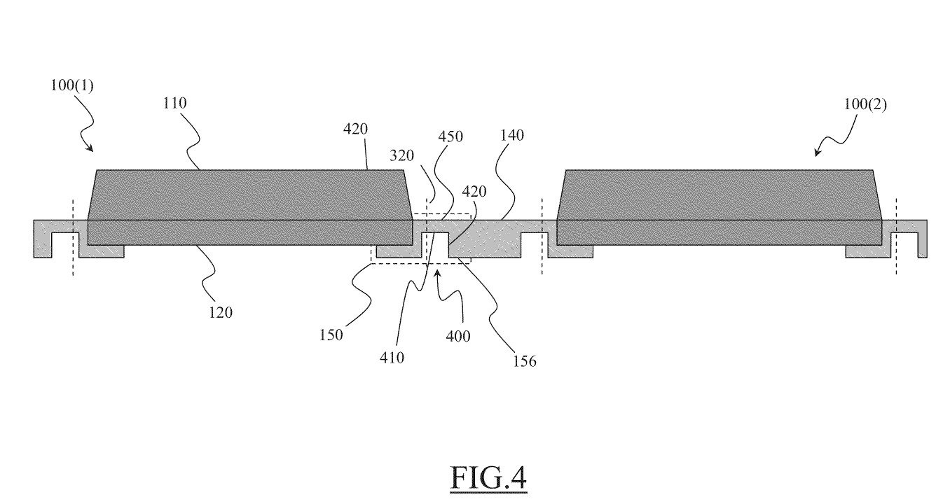

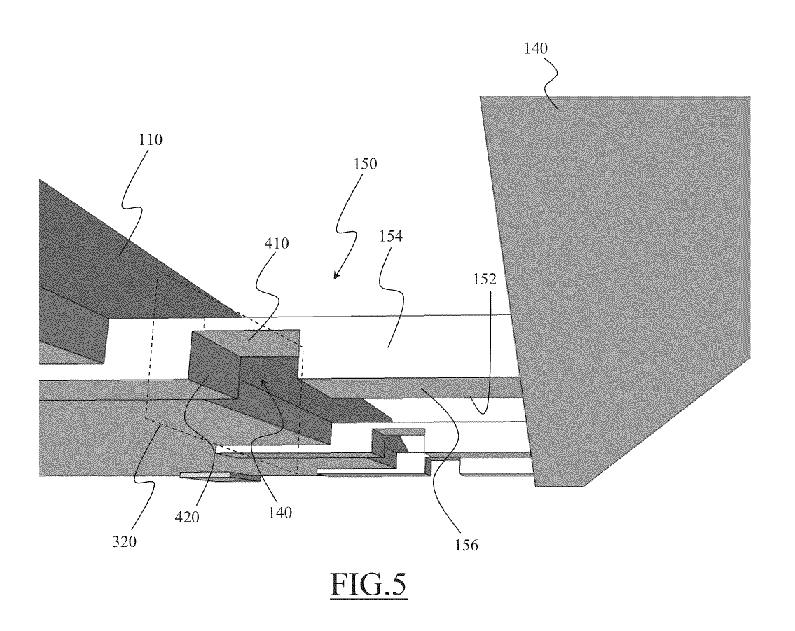

FIG. 4 is a sectional view of the support structure and of the electronic devices illustrated in FIG. 3 taken along the line III-III, while FIG. 5 is a bottom perspective view of the detail of FIG. 3 identified by the reference 310. The grooves obtained by the removal of portions of material from the pin blocks 150 are identified in this figure with the reference 400. As shown in FIGS. 4 and 5, each groove 400 has an inner surface comprising a central superficial portion 410 which extends substantially parallel to the lower face 156 of the corresponding pin block 150 and two faced side superficial portions 420 which extend substantially perpendicularly to the face 156.

The portions of the pin blocks 150 located between the grooves 400 and the insulating body 110 are still linked to the portions located between the grooves 400 themselves and the junction sacrificial portions 140 of the support structure 130 via connection portions 450 (of the pin blocks) located between the central superficial portion 410 of the grooves 400 and the upper face of the pin blocks 150.

Preferably, but not necessarily, the depth of the groove 400 along the direction perpendicular to the face 156, corresponding to the height of the side superficial portions 420, is at least 70% of the total thickness (along the direction perpendicular to the face 156) of the pin block.

Although the grooves 400 have been illustrated in FIGS. 4 and 5 with a central superficial portion 410 which is flat and exactly parallel to the lower face 156 of the corresponding pin block 150, and with the lateral superficial portions 420 which are flat and exactly perpendicular to the lower face 156 of the corresponding pin block 150, the concepts of the present invention may also be applied in case the grooves have different shapes, for example, with the side and/or central surfaces that are curved or inclined.

Once the grooves 400 have been formed—depending on the mechanical features of the material forming the substrate 130 and the technology used to make the grooves 400—a deburring phase (mechanical, laser or other known technique considered effective) may be required to remove burrs formed during the formation of the grooves. Subsequently, the pin blocks 150 are covered with soldering material (plating operation) by means of electroplating, by immersing the support structure 130 in a galvanic bath and imposing a potential difference between the support structure 130, which acts as a cathode, and an element that acts as an anode, for example through a current generator. It is emphasized that the presence of the grooves 400 does not prevent the portions of the pin blocks 150 located between the grooves 400 themselves and the insulating body 110 to assume the same electric potential of the portions located between the grooves 400 and the junction sacrificial portions 140 of the support structure 130, since the first portions are electrically connected with the second portions through the corresponding connection portions 450.

Following this operation, the layer of soldering material (e.g., tin) is deposited on the internal surfaces of the grooves 400 as well, i.e., the central 410 and side 420 superficial portions.

Referring jointly to FIGS. 3-5, the electronic devices 100(i) are then separated from the support structure 130 (cropping operation) by sectioning the pin blocks 150 at the grooves 400. According to an embodiment of the present invention, the electronic devices 100(i) are separated from the support structure 130 by sectioning the connection portions 450 of the pin blocks 150 at the junction between the connection portions 450 themselves and the corresponding portions of pin block 150 between groove 400 and insulating body 110 along section planes 320 substantially perpendicular to the face 156 of the pin blocks 150.

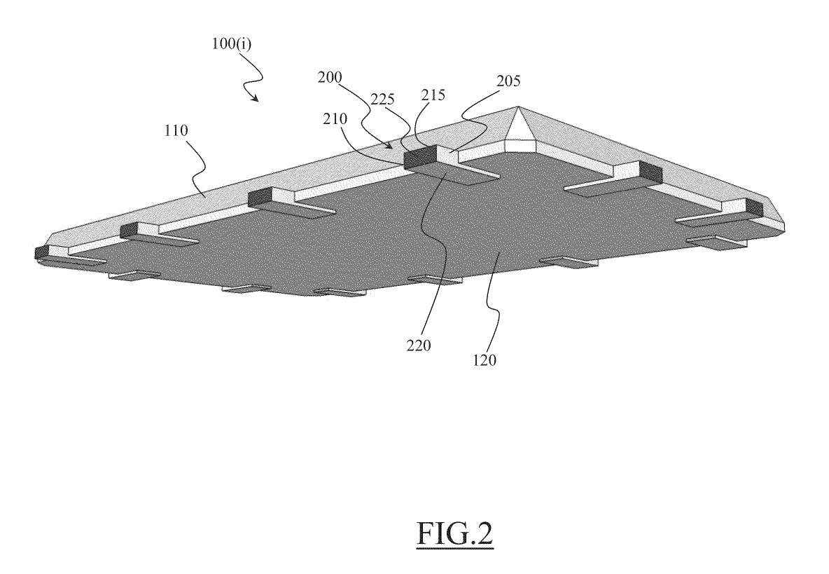

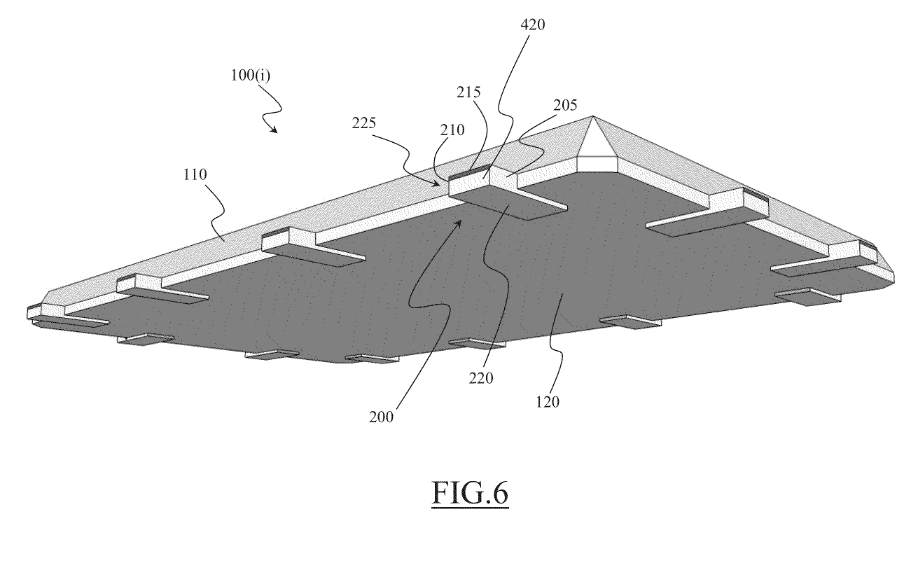

FIG. 6 is a perspective view of an electronic device 100(i) obtained with the manufacturing process in accordance with embodiments of the invention just described. The electronic device 100(i) has a plurality of pins 200 exposed from the insulating body 110 obtained starting from the pin blocks 150 as a result of the cropping operation described above. In contrast to the pins of the electronic device shown in FIG. 2 obtained by means of the known manufacturing processes, whose front faces were not be covered by the soldering material, the front faces of the pins of the electronic device of FIG. 6 are largely covered by soldering material. In fact, according to the proposed process, a part of the front face 225 of each pin 200 of the electronic device 100(i) of FIG. 6 is formed by a lateral superficial portion 420 (covered by soldering material) of the groove which has been formed on the pin block from which the pin itself has been originated.

Thanks to the presence of soldering material on the front face 225 of the pins 200, during the assembly operations of the electronic device 100(i) to a printed circuit board, when the solder paste in contact with the lower faces 220 of the pins 200 begins to melt, a part of the molten material located below the lower faces 220 tends to rise towards the front faces 225, because these are formed in a material (tin) with a high degree of wettability. Therefore, in order to check whether the electronic device 100(i) produced according to the present invention has been properly connected to the printed circuit board, it is sufficient to inspect the front faces of the pins, unlike known solutions, which provide instead to access the lower part of the electronic device in contact with the printed circuit board to inspect the bottom faces of the pins.

Naturally, to the solution described above one skilled in the art, in order to satisfy contingent and specific requirements, may apply numerous modifications and variations.

For example, the number, shape and/or arrangement of the pins of the electronic devices can be different from those used in the description. Similar considerations apply to the insulating body, which can have a different shape from the described one.

In addition, although in the description reference has been explicitly made to a support structure (and therefore pins) made in copper, and tin as a soldering material, the concepts of the present invention may also be applied to different materials.

What is claimed is:

1. A method, comprising:
forming a groove extending transversal to a leadframe pin block, said leadframe pin block extending away from a side of an encapsulated semiconductor device, said groove including a side wall;
covering surfaces of the pin block including said side wall with a solder material layer;
sectioning the pin block at the groove to define a pin for the encapsulated semiconductor device having an outer end formed in part by said solder material layer covered side wall and in part by a sectioned portion of the pin block not covered by said solder material layer.

2. The method of claim 1, further comprising:
providing a leadframe support structure including a support cell having a support substrate, junction sacrificial portions surrounding the substrate support, and pin blocks which extend from the junction sacrificial portions towards the support substrate, each pin block having a first end connected to a junction sacrificial portion and a second end opposite to the first end.

3. The method of claim 2, further comprising: connecting a semiconductor material chip integrating at least one electronic component to the support substrate and connecting terminals of the semiconductor material chip to the second ends of respective pin blocks.

4. The method of claim 3, further comprising: encapsulating the semiconductor material chip and the second ends of the pin blocks within an insulating body.

5. The method of claim 1, wherein the pin block has a bottom surface and wherein forming the groove comprises forming the groove in said bottom surface.

6. The method of claim 1, wherein the groove defines a bottom surface defining a linking portion and wherein sectioning the pin block comprises sectioning the pin block through said linking portion.

7. The method of claim 1, further comprising de-burring the pin block following formation of said groove.

8. The method of claim 1, wherein said covering comprises electroplating the pin block and groove side wall.

9. A method, comprising:
a) providing a support structure in conductive material comprising a support cell for each electronic device to be manufactured, each support cell comprising: a support substrate, junction sacrificial portions surrounding the substrate support, and pin blocks which extend from the junction sacrificial portions towards the substrate support, each pin block having a first end connected to a junction sacrificial portion and a second end opposite to the first end,
in each support cell:
b) connecting a semiconductor material chip integrating at least one electronic component to the corresponding support substrate;
c) connecting terminals of the chip to the second ends of respective pin blocks of the support cell;
d) encapsulating the chip and the second ends of the pin blocks into a corresponding insulating body;
e) removing a portion of conductive material from each pin block between the first and the second ends to form a corresponding groove transversal to the pin block itself;
f) covering the pin blocks and the inner surfaces of the corresponding grooves with a soldering material, and
g) sectioning each pin block at the corresponding groove to obtain a corresponding pin having a first end corresponding to a portion of the inner surface of the groove and a second end corresponding to the second end of the pin block, said sectioning causing the separation of the chip-insulating body-pins assembly from the junction sacrificial portions.

10. The method according to claim 9, wherein each one of said pin blocks has a substantially parallelepiped shape comprising a first side face, a second side face, a bottom face and a top face which extend along a direction perpendicular to the corresponding junction sacrificial portion, said top and bottom faces being parallel to a rear surface of the insulating body, said first side face and said second side face being perpendicular to said rear surface, said removing a portion of conductive material from each pin block comprising removing conductive material from the bottom face of the pin block in such a way that the groove transversally crosses the pin block from the first side face to the second side face.

11. The method according to claim 10, wherein the internal surface of each groove comprises a central superficial portion which extends substantially parallel to the bottom face of the pin block and two side superficial portions which extends substantially perpendicular to the bottom face of the pin block, said first end and said second end of the pin block being connected one to another after the groove formation through a corresponding linking portion of the pin block located between the top surface of the pin block and the central superficial portion of the groove, said sectioning each pin block at the groove comprising sectioning the pin block at the corresponding linking portion.

12. The method according to claim 11, wherein said sectioning the pin block at the linking portion comprises sectioning the pin block at a junction between the linking portion and the pin block portion which extends from the second end to the corresponding groove.

13. The method according to claim 9, wherein said removing a portion of conductive material from each pin block comprises removing the portion of conductive material by means of milling or grinding and then removing working burrs which have been possibly formed during said milling or grinding.

14. The method according to claim 9, wherein said covering the pin blocks and the internal surfaces of the corresponding grooves with a soldering material comprises plating the pin block and the internal surfaces of the corresponding grooves by means of an electroplating process.

15. An electronic device, comprising:
an encapsulated semiconductor device;
wherein said semiconductor device is mounted to a leadframe, said leadframe including a plurality of pins, said pins extending perpendicular to a side of an encapsulating material block;
a solder layer covering said pins;
wherein each pin has an outer end formed in part by a solder material layer covered portion and in part by a sectioned portion not covered by said solder material layer.
